(19) United States
(12) Patent Application Publication
(10) Pub. No.: US 2026/0334267 A1
(43) Pub. Date: Oct. 22, 2026

(54) PACKAGE SUBSTRATE INCLUDING FIBER-REINFORCED DIELECTRIC LAYER, PACKAGE STRUCTURE INCLUDING THE PACKAGE SUBSTRATE AND METHOD OF FORMING THE SAME

(71) Applicant: Taiwan Semiconductor Manufacturing Company Limited, Hsinchu (TW)

(72) Inventors: Yu-Huan Chen, Taoyuan City (TW); Kuo-Ching Hsu, Taipei (TW)

(21) Appl. No.: 19/722,837

(22) Filed: Jun. 27, 2026

Related U.S. Application Data
(63) Continuation of application No. 18/889,666, filed on Sep. 19, 2024.
(60) Provisional application No. 63/657,676, filed on Jun. 7, 2024.

(51) Int. Cl. H10W 70/685; H10W 42/00; H10W 70/05; H10W 70/65; H10W 70/692; H10W 90/00

(52) U.S. Cl. CPC H10W 70/685; H10W 42/121; H10W 70/05; H10W 70/65; H10W 70/692; H10W 90/00; H10W 90/701

(57) ABSTRACT

A package substrate includes a core, a first dielectric layer on a first side of the core, a second dielectric layer on a second side of the core opposite the first side of the core, and a fiber-reinforced dielectric layer on at least one of the first side of the core or the second side of the core. A method of forming a package substrate includes forming a first dielectric layer on a first side of a core, forming a second dielectric layer on a second side of the core opposite the first side of the core, and forming a fiber-reinforced dielectric layer on at least one of the first side of the core or the second side of the core.

### RELATED APPLICATIONS

This application is a continuation of U.S. Patent Application No. 18/889,666, entitled “Package Substrate Including Fiber-Reinforced Dielectric Layer, Package Structure Including the Package Substrate an Methods of Forming the Same,” filed Sep. 19, 2024, which claims the benefit of priority from U.S. Provisional Application No. 63/657,676 entitled “Anti-crack Substrate for Package level reliability survival,” filed Jun. 7, 2024, the entire contents of each of which are hereby incorporated by reference for all purposes.

### BACKGROUND

Cracks in semiconductor package substrates may result from a variety of causes, often linked to mechanical, thermal, and environmental stresses. Mechanical stresses on a package substrate may occur, for example, in testing, assembly, affixing the package substrate to a printed circuit board (PCB), and so on. Thermal stresses on the package substrate may be caused by thermal cycling or by mismatch in material coefficients of thermal expansion (CTE). Environmental stresses on the package substrate may be caused, for example, by exposure to moisture or corrosive chemicals.

Manufacturers may use various strategies to inhibit crack formation in semiconductor package substrates. Using materials with similar CTE may mitigate against crack formation. Other strategies may focus on increasing the rigidity of the package substrate to mitigate against crack formation. For example, the incorporation of a rigid core in the package substrate is often used to provide rigidity to the package substrate. Manufacturers may also insert rigid structures such as metal pillars into the package substrate to provide rigidity to the package substrate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of a package substrate according to one or more embodiments.

FIG. 2A is an illustration of the first fiber sheet in the fiber-reinforced dielectric layer according to one or more embodiments.

FIG. 2B is an illustration of the first fiber sheet in the fiber-reinforced dielectric layer having a first alternative configuration according to one or more embodiments.

FIG. 3A is a vertical cross-sectional view of the package structure according to one or more embodiments.

FIG. 3B is a plan view (top-down view) of the package structure, according to one or more embodiments.

FIG. 3C is a vertical cross-sectional view of the upper fiber-reinforced dielectric layer according to one or more embodiments.

FIG. 3D is a vertical cross-sectional view of the lower fiber-reinforced dielectric layer according to one or more embodiments.

FIG. 4A is a vertical cross-sectional view of an intermediate structure including the first dielectric layer on the core according to one or more embodiments.

FIG. 4B is a vertical cross-sectional view of an intermediate structure including the upper fiber-reinforced dielectric layer according to one or more embodiments.

FIG. 4C is a vertical cross-sectional view of an intermediate structure including the second dielectric layer on the core according to one or more embodiments.

FIG. 4D is a vertical cross-sectional view of an intermediate structure including the lower fiber-reinforced dielectric layer according to one or more embodiments.

FIG. 4E illustrates a vertical cross-sectional view of an intermediate structure in which the semiconductor module may be mounted on the package substrate (e.g., via a flip chip bonding (FCB) process) according to one or more embodiments.

FIG. 4F illustrates a vertical cross-sectional view of an intermediate structure in which the package underfill layer may be formed on the package substrate according to one or more embodiments.

FIG. 4G illustrates a vertical cross-sectional view of an intermediate structure in which the adhesive may be applied to the package substrate according to one or more embodiments.

FIG. 4H illustrates a vertical cross-sectional view of an intermediate structure in which the stiffener ring may be attached to (e.g., mounted on) the package substrate according to one or more embodiments.

FIG. 4I illustrates a vertical cross-sectional view of an intermediate structure in which a plurality of solder balls may be formed on the package substrate according to one or more embodiments.

FIG. 5 is a flow chart illustrating a method of making a semiconductor package according to one or more embodiments.

FIG. 6 is a flow chart illustrating a method of making a semiconductor package according to one or more embodiments.

FIG. 7 is a vertical cross-sectional view of a package structure having a first alternative configuration according to one or more embodiments.

FIG. 8A is a vertical cross-sectional view of the package structure having a second alternative configuration according to one or more embodiments.

FIG. 8B is a top down view (plan view) of the package structure having a second alternative configuration according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

A cored substrate (e.g., an Ajinomoto Build-up Film (ABF) cored package substrate) may include a core and build-up dielectric layers on the top and bottom sides of the core. The core may include, for example, a woven glass cloth embedded in an epoxy resin (e.g., FR-4), a thermosetting resin such as bismaleimide - triazine resin (BT resin), polyimide and/or a ceramic material (e.g., alumina, aluminum nitride). The build-up dielectric layers may include an applied filler base dielectric film (e.g., epoxy resin, polyimide, etc.) for full redistribution layers (RDL).

However, cored substrates may have a problem in surviving post-component level reliability (CLR) testing, especially thermal cycling (TC) and high-temperature stress (HTS) testing. A major failure mode may include a crack in the resin film caused by high package stress. In particular, a resin base dielectric film may be unable to afford high bending stress during package reliability testing. The dielectric film may have a weakness at a top side and/or bottom side of the package substrate.

The failure rate may be especially high for package substrates having a large unit size such as for artificial intelligence (AI) and high-performance computing (HPC) applications. Package substrates with a large body and/or large layer count (e.g., large RDL layer count) may have greater package stress that may cause a crack in the package substrate during package level reliability testing.

One or more embodiments of the present disclosure may include a robust package substrate (e.g., anti-crack substrate) capable of surviving package level reliability testing (e.g., CLR testing). The package substrate may include a fiber-reinforced dielectric layer that may strengthen the package substrate and inhibit formation of a crack in the dielectric film at a top side and/or bottom side of the package substrate. The fiber-based dielectric layers inside the package substrate may help to ensure that the whole package substrate survives post CLR and that cracks will be stopped according to stab test result. Meanwhile, the fiber-based dielectric layers can maintain the same continuity function as typical build-up layers.

In at least one embodiment, applied fiber-reinforced layers (e.g., anti-crack layers) may be formed at both sides of outer layers of the package substrate. The fiber- reinforced layer may allow the package substrate to sustain high stress from package level bending during reliability testing. The fiber-reinforced layers may include, for example, a fiber-based dielectric film applied at both top side and bottom side of the package substrate.

The fiber-based dielectric film may further include blind vias and traces and pads for continuities. The fiber-based dielectric film (e.g., anti-crack layer with fiber inside) can protect the package substrate against stress from package level bending during reliability testing and may inhibit (e.g., stop) initial crack formation into inner layers of the package substrate. The fiber-based dielectric film may enhance rigidity, improve crack-proof capabilities at both sides of package substrate, and enable survival of package substrate post-reliability testing.

In at least one embodiment, the fiber-reinforced layers (e.g., anti-crack layers) may be formed at both sides of the outer layers of the package substrate and may also be formed at other locations. Including additional fiber-reinforced layers may further improve the crack-proof capabilities of the package substrate.

The package substrate (e.g., ABF package substrate) with fiber-reinforced layers may sustain package level reliability performance from the high stress of a large body size package such as a package that is greater than 60 mm x 60 mm for HPC/AI application. The fiber-reinforced layers may inhibit substrate dielectric layer crack post-package level testing (e.g., TC & HTS). The package substrate may be made by applying a fiber-based build-up film at both the top side and the bottom side of outer layers to inhibit (e.g., prevent) a package stress-induced initial crack or crack propagation post-reliability testing.

In at least one embodiment, the elements of the package substrate may include a core-based ABF substrate, a large body size, dielectric build up (BU) layers for routing, fiber-reinforced layers (e.g., dielectric layer with fiber cloth inside), solder resist layer (e.g., solder mask), solder bump (e.g., C4 bumps) having a predetermined pitch, a plurality of metal vias in a top fiber-reinforced layer, a plurality of vias in a bottom fiber-reinforced layer, a semiconductor module (e.g., chip-on-wafer (CoW), multi-chip module (McM), interposer module, etc.), a stiffener ring (e.g., package ring).

In at least one embodiment, one or more fibers (e.g., fiber layers) may be present in cloth type inside a dielectric material in a build-up (BU) layer of the package substrate. The fiber layers may be composed of inorganic material such as glass, SiO₂, Al₂O₃, Ca, B, Mg, etc. The package substrate may have a body size greater than about 2500 mm². The fiber-reinforced dielectric layer may have a thickness greater than about 20 µm with fiber cloth layer having a thickness greater than about 10 µm inside. A bump pitch of a semiconductor die or semiconductor module mounted on the package substrate may be greater than about 90 µm. An aspect ratio of the metal vias in the upper fiber-reinforced dielectric layer may be in a range from 0.3 to 1. An aspect ratio of the metal vias in the lower fiber-reinforced dielectric layer may be in a range from 0.2 to 0.9.

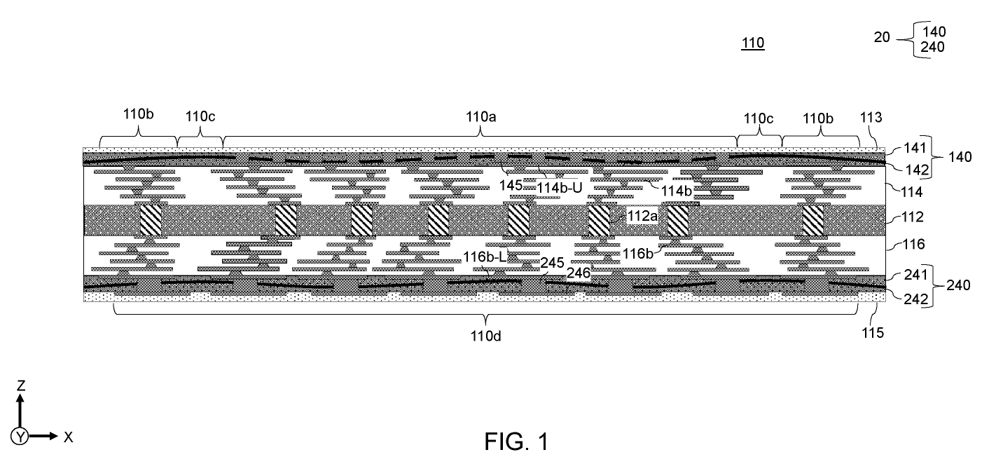

FIG. 1 is a vertical cross-sectional view of a package substrate 110 according to one or more embodiments. The package substrate 110 may include a large-size package substrate 110. In at least one embodiment, the package substrate 110 may have an area (e.g., in the x-y plane) greater than about 2500 mm². In at least one embodiment, the package substrate 110 may have an area greater than about 60 mm x 60 mm. In at least one embodiment, the package substrate 110 may be utilized in a package structure having a high performance computing (HPC)/ Artificial Intelligence (AI) application(s).

As illustrated in FIG. 1, the package substrate 110 may include a die mounting region 110a on a chip side (e.g., top side) of the package substrate 110. The die mounting region 110a may be configured to have one or more semiconductor dies, semiconductor modules or interposer modules subsequently mounted thereon. The package substrate 110 may also include a ring mounting region 110b on the chip side of the package substrate 110. The ring mounting region 110b may be at least partially around the die mounting region 110a. The ring mounting region 110b may be configured to have a stiffener ring or a foot portion of a package lid mounted thereon. The package substrate 110 may also include a separation region 110c that separates the ring mounting region 110b from the die mounting region 110a.

The package substrate 110 may also include a BGA region 110d on a board side (e.g., bottom side) of the package substrate. The BGA region 100d may be configured to have the solder balls 191 of a BGA 190 mounted thereon. As illustrated in FIG. 1, the BGA region 100d may be overlapped by the die mounting region 100a, the ring mounting region 100b and the separation region 100c.

As further illustrated in FIG. 1, the package substrate 110 may include a core 112, a first dielectric layer 114 on a first side (e.g., chip side) of the core 112, and a second dielectric layer 116 on a second side (e.g., board side) of the core 112 opposite the first side of the core 112.

The package substrate 110 may also include a fiber-reinforced dielectric layer 20 on at least one of the first side of the core 112 or the second side of the core 112. In at least one embodiment, the fiber-reinforced dielectric layer 20 may include an upper fiber-reinforced dielectric layer 140 on the first side of the core 112 and a lower fiber-reinforced dielectric layer 240 on the second side of the core 112. The fiber-reinforced dielectric layer 20 may help to inhibit a crack in the package substrate 110.

The package substrate 110 may include a build-up film substrate such as an Ajinomoto build-up film (ABF) substrate. That is, in at least one embodiment, each of the first dielectric layer 114 and the second dielectric layer 116 may include an ABF layer. In at least one embodiment, each of the first dielectric layer 114 and the second dielectric layer 116 may include at least five build-up (BU) layers.

The core 112 may help to provide rigidity to the package substrate 110. The core 112 may include, for example, an epoxy resin, a thermosetting resin such as bismaleimide - triazine resin (BT resin), polyimide and/or a ceramic material (e.g., alumina, aluminum nitride). Other suitable dielectric materials are within the contemplated scope of disclosure.

The core 112 may also include a sheet of reinforcement material embedded therein. The sheet of reinforcement material may include, for example, a fiberglass cloth sheet (e.g., woven fiberglass cloth sheet). In at least one embodiment, the core 112 may include a fiberglass cloth sheet embedded in a resin such as an epoxy resin (e.g., FR-4). The core 112 may include, for example, a woven fiberglass sheet laminate.

The core 112 may include one or more through vias 112a. The through vias 112a may extend from a lower surface of the core 112 to an upper surface of the core 112. The through vias 112a may allow an electrical connection between the first dielectric layer 114 and the second dielectric layer 116. The through vias 112a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The first dielectric layer 114 may be formed on an upper surface of the core 112. The first dielectric layer 114 may include a plurality of layers and, in particular, may include a build-up film (e.g., ABF). The first dielectric layer 114 may also include an organic material such as a polymer material. In particular, the first dielectric layer 114 may include a plurality of layers including dielectric polymer material such as polyimide (PI), benzocyclobutene (BCB), or polybenzobisoxazole (PBO). Other suitable dielectric materials are within the contemplated scope of disclosure.

The first dielectric layer 114 may also include one or more first metal interconnect structures 114b. The first metal interconnect structures 114b may include an redistribution layer (RDL) structure. The first metal interconnect structures 114b may contact the through vias 112a in the core 112. The first metal interconnect structures 114b may include metal layers (e.g., copper traces) and metal vias connecting the metal layers. The first metal interconnect structures 114b may include an uppermost metal trace 114b-U located on an upper surface of the first dielectric layer 114. The first metal interconnect structures 114b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The second dielectric layer 116 may be formed on a lower surface of the core 112. The second dielectric layer 116 may also include a plurality of layers and, in particular, may include a build-up film (e.g., ABF). The second dielectric layer 116 may also include an organic material such as a polymer material. In particular, the second dielectric layer 116 may include a dielectric polymer material such as polyimide (PI), benzocyclobutene (BCB), or polybenzobisoxazole (PBO). Other suitable dielectric materials are within the contemplated scope of disclosure.

The second dielectric layer 116 may also include one or more second metal interconnect structures 116b. The second metal interconnect structures 116b may contact the through vias 112a in the core 112 and may be electrically coupled to the first metal interconnect structures 114b by the through vias 112a in the core 112. The second metal interconnect structures 116b may include metal layers (e.g., copper traces) and metal vias connecting the metal layers. The second metal interconnect structures 116b may include a lowermost metal trace 116b-L located on a lower surface of the second dielectric layer 116. The second metal interconnect structures 116b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The upper fiber-reinforced dielectric layer 140 may be formed on the first dielectric layer 114. In at least one embodiment, the upper fiber-reinforced dielectric layer 140 may be included within the build-up layers of the first dielectric layer 114. The upper fiber-reinforced dielectric layer 140 may include a layer of dielectric material 141 and one or more fiber sheets 142 embedded in the layer of dielectric material 141. The dielectric material 141 may include a material substantially similar to the material in the first dielectric layer 114. The dielectric material 141 may include a dielectric polymer material such as polyimide (PI), benzocyclobutene (BCB), or polybenzobisoxazole (PBO). Other suitable dielectric materials are within the contemplated scope of disclosure.

The dielectric material 141 may have a thickness (in the z-direction) less than a thickness of the first dielectric layer 114. In at least one embodiment, the thickness of the dielectric material layer 141 may be in a range from 10% to 40% of the thickness of the first dielectric layer 114. In at least one embodiment, the dielectric material 141 may have a thickness greater than about 20 µm. In at least one embodiment, the dielectric material 141 may have a thickness at least twice the thickness of the fiber sheet 142. Other thicknesses are within the contemplated scope of disclosure.

The fiber sheet 142 may be configured as a cloth or fabric having one or more layers of fibers (e.g., fiber layers). The fiber sheet 142 may be composed of an inorganic material such as glass, SiO₂, Al₂O₃, Ca, B, Mg, etc. Other suitable dielectric materials are within the contemplated scope of disclosure. The fiber sheet 142 may have a thickness greater than about 10 µm. Other thicknesses are within the contemplated scope of disclosure.

The upper fiber-reinforced dielectric layer 140 may also include a plurality of upper metal vias 145 (e.g., blind vias with solder on pad (SOP) or pre-solder at substrate) in the die mounting region 110a of the package substrate 110. The upper metal vias 145 may be configured to be contacted by solder bumps (e.g., C4 bumps) of a semiconductor die or semiconductor module (e.g., interposer module) mounted on the package substrate 110.

A pitch of the upper metal vias 145 may be substantially the same as a bump pitch of the semiconductor die or semiconductor module to be mounted on the package substrate 110. In at least one embodiment, the pitch of the upper metal vias 145 may be greater than about 90 µm. However, other values of the pitch for the upper metal vias 145 are within the contemplated scope of disclosure.

The upper metal vias 145 may have an upper surface that is substantially coplanar with an upper surface of the dielectric material 141. The upper metal vias 145 may extend through openings in the fiber sheet 142 and contact an upper surface of the uppermost metal trace 114b-U of the first metal interconnect structures 114b. The upper metal vias 145 may have a substantially trapezoidal cross-sectional shape. An aspect ratio of the upper metal vias 145 may be in a range from 0.3 to 1. Other cross-sectional shapes and aspect ratios are within the contemplated scope of disclosure.

The upper fiber-reinforced dielectric layer 140 may extend over an entirety of the package substrate 110. In particular, the upper fiber-reinforced dielectric layer 140 may be located in the die mounting region 110a, the ring mounting region 110b and the separation region 110c between the die mounting region 110a and ring mounting region 110b. The separation region 110c may be highly susceptible to crack formation and, therefore, locating the upper fiber-reinforced dielectric layer 140 in the separation region 110c may be especially helpful in inhibiting cracks in the package substrate 110 (e.g., cracks in the first dielectric layer 114).

The package substrate 110 may also include an upper solder resist layer 113 (e.g., solder mask layer) on the upper fiber-reinforced dielectric layer 140. The upper solder resist layer 113 may include a thin layer of polymer material (e.g., epoxy polymer). The upper solder resist layer 113 may have a thickness in a range from about 5µm to 50 µm. In at least one embodiment, the upper solder resist layer 113 may have a thickness in a range from about 10µm to 30 µm. Greater or lesser thickness of the upper solder resist layer 113 may be used.

The upper solder resist layer 113 may be formed so as to cover the upper metal vias 145 and other metal features (e.g., conductive lines, copper traces) on the chip-side surface of the package substrate 110. The upper solder resist layer 113 may protect the upper metal vias 145 and other metal features from oxidation. The upper solder resist layer 113 may also prevent solder bridges (e.g., unintended electrical connections) from forming between closely spaced metal features.

The lower fiber-reinforced dielectric layer 240 may be formed on a bottom surface of the second dielectric layer 116. In at least one embodiment, the lower fiber-reinforced dielectric layer 240 may be included within the build-up layers of the second dielectric layer 116. The lower fiber-reinforced dielectric layer 240 may include a layer of dielectric material 241 and one or more fiber sheets 242 embedded in the layer of dielectric material 241. The dielectric material 241 may include a material substantially similar to the material in the second dielectric layer 116. The dielectric material 241 may include a dielectric polymer material such as polyimide (PI), benzocyclobutene (BCB), or polybenzobisoxazole (PBO). Other suitable dielectric materials are within the contemplated scope of disclosure.

The dielectric material 241 may have a thickness (in the z-direction) less than a thickness of the second dielectric layer 116. In at least one embodiment, the thickness of the dielectric material layer 241 may be in a range from 10% to 40% of the thickness of the second dielectric layer 116. In at least one embodiment, the dielectric material 241 may have a thickness greater than about 20 µm. In at least one embodiment, the dielectric material 241 may have a thickness at least twice the thickness of the fiber sheet 142. In at least one embodiment, the thickness of the dielectric material 241 may be greater than the thickness of the dielectric material 141 in the upper fiber-reinforced dielectric layer 140. Other thicknesses are within the contemplated scope of disclosure.

The fiber sheet 242 may be configured as a cloth or fabric having one or more layers of fibers (e.g., fiber layers). The fiber sheet 242 may be composed of an inorganic material such as glass, SiO₂, Al₂O₃, Ca, B, Mg, etc. Other suitable dielectric materials are within the contemplated scope of disclosure. The fiber sheet 242 may have a thickness greater than about 10 µm. Other thicknesses are within the contemplated scope of disclosure.

The lower fiber-reinforced dielectric layer 240 may also include a plurality of lower metal vias 245 in the BGA region 110d of the package substrate 110. The lower metal vias 245 may be configured to be contacted by solder balls 191 of a BGA 190 to be formed on the board-side surface of the package substrate 110. A pitch of the lower metal vias 245 may be substantially the same as a solder ball pitch of the BGA 190.

The lower metal vias 245 may have a pitch greater than the pitch of the upper metal vias 145. The lower metal vias 245 may have a size greater than a size of the upper metal vias 145. In particular, a thickness of the lower metal vias 245 may be greater than a thickness of the upper metal vias 145. A width of the lower metal vias 245 may also be greater than a width of the upper metal vias 145.

The lower metal vias 245 may have a lower surface that is substantially coplanar with a lower surface of the dielectric material 241. The lower metal vias 245 may extend through openings in the fiber sheet 142 and contact a lower surface of the lowermost metal trace 116b-L of the second metal interconnect structures 116b. The lower metal vias 245 may have a substantially trapezoidal cross-sectional shape. An aspect ratio of the lower metal vias 245 may be in a range from 0.2 to 0.9. Other cross-sectional shapes and aspect ratios are within the contemplated scope of disclosure.

As further illustrated in FIG. 1, the package substrate 110 may also include bonding pads 246 contacting the surface of the lower metal vias 245. The bonding pads 246 may be formed on the lower surface of the dielectric layer 241. The bonding pads 246 may have a width greater than the width of the lower metal vias 245. The bonding pads 246 may be configured to serve as a mounting surface for the solder balls 191 of the BGA 190. The bonding pads 246 may be formed of the same material as the lower metal vias 245. Other materials are within the contemplated scope of disclosure.

The lower fiber-reinforced dielectric layer 240 may extend over an entirety of the package substrate 110. In particular, the lower fiber-reinforced dielectric layer 240 may be located in the BGA region 110d. In at least one embodiment, the lower fiber-reinforced dielectric layer 240 may be located under the separation region 110c which may be especially helpful in inhibiting cracks in the package substrate 110 (e.g., cracks in the second dielectric layer 116).

The package substrate 110 may also include a lower solder resist layer 115 (e.g., solder mask layer) on the lower fiber-reinforced dielectric layer 240 and over the bonding pads 246. The lower solder resist layer 115 may include a thin layer of polymer material (e.g., epoxy polymer). The lower solder resist layer 115 may have a thickness in a range from about 5µm to 50 µm. In at least one embodiment, the lower solder resist layer 115 may have a thickness in a range from about 10µm to 30 µm. Greater or lesser thickness of the lower solder resist layer 115 may be used.

The lower solder resist layer 115 may be formed so as to cover the lower metal vias 245 and other metal features (e.g., conductive lines, copper traces) on the board-side surface of the package substrate 110. The lower solder resist layer 115 may protect the lower metal vias 245 and other metal features from oxidation. The lower solder resist layer 115 may also prevent solder bridges (e.g., unintended electrical connections) from forming between closely spaced metal features.

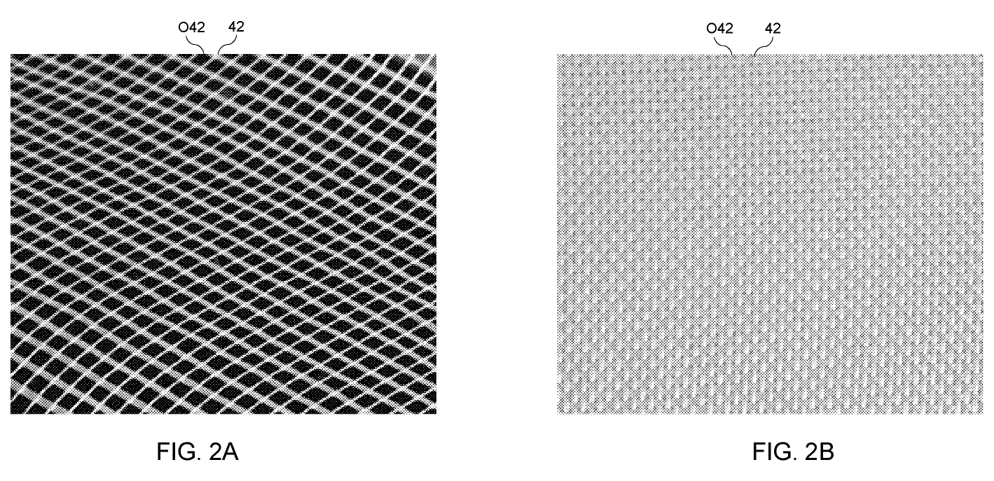

FIG. 2A is an illustration of the fiber sheet 142, 242 in the fiber-reinforced dielectric layer 20 according to one or more embodiments. As illustrated in FIG. 2A, the fiber sheet 142, 242 may include a fiber mesh sheet. The fiber mesh sheet may include fibers 42 extending in a first direction and fibers 42 extending in a second direction perpendicular to the first direction. The fibers 42 may be composed of glass, SiO₂, Al₂O₃, Ca, B, Mg, etc. The fibers 42 may have a diameter greater than about 10 µm. The fiber mesh sheet may also include openings O42 between the fibers 42. The openings O42may have a substantially square shape. The openings O42 may have an area in range from 100 µm² x 5000 µm². Areas of greater or lesser size are within the contemplated scope of disclosure.

FIG. 2B is an image of the fiber sheet 142, 242 in the fiber-reinforced dielectric layer 20 having a first alternative configuration according to one or more embodiments. As illustrated in FIG. 2B, the fiber sheet 142, 242 having the first alternative configuration may include a woven fiber cloth. The woven fiber cloth may include fibers 42 extending in a first direction interwoven with fibers 42 extending in a second direction perpendicular to the first direction. The weave type of the woven fiber cloth may include plain weave, satin weave, etc. Other types of weaves are within the contemplated scope of disclosure. The fibers 42 in the woven fiber cloth may also be composed of glass, SiO₂, Al₂O₃, Ca, B, Mg, etc. and may also have a diameter greater than about 10 µm. The woven fiber cloth may also include openings O42 between the fibers 42. The openings O42 may have an area in range from 25 µm² x 1000 µm². Areas of greater or lesser size are within the contemplated scope of disclosure.

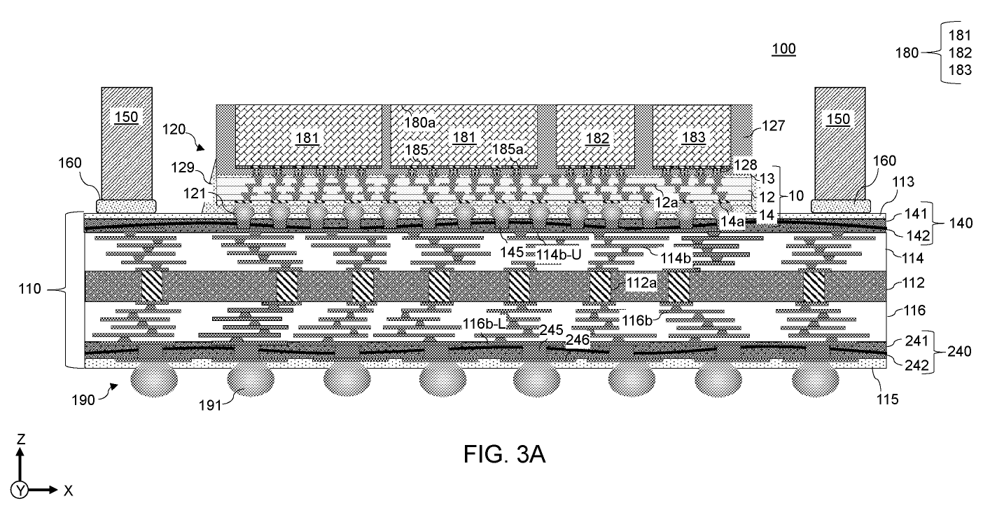

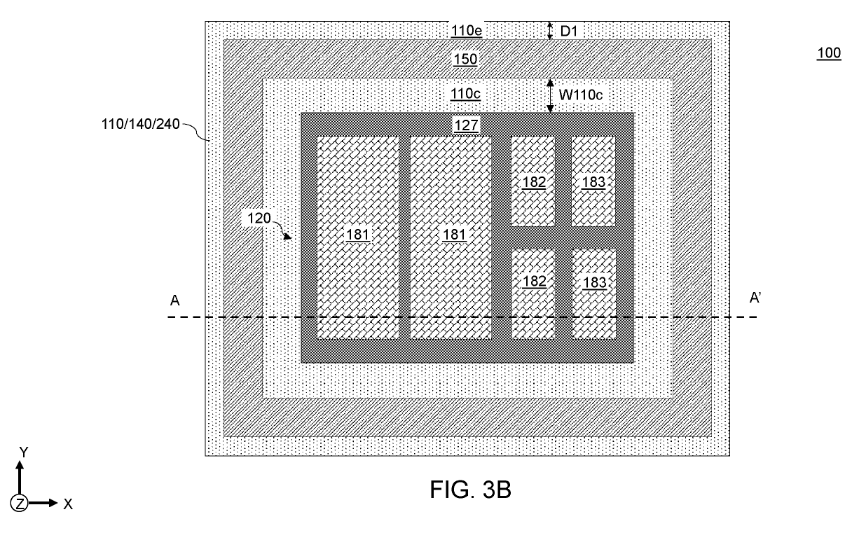

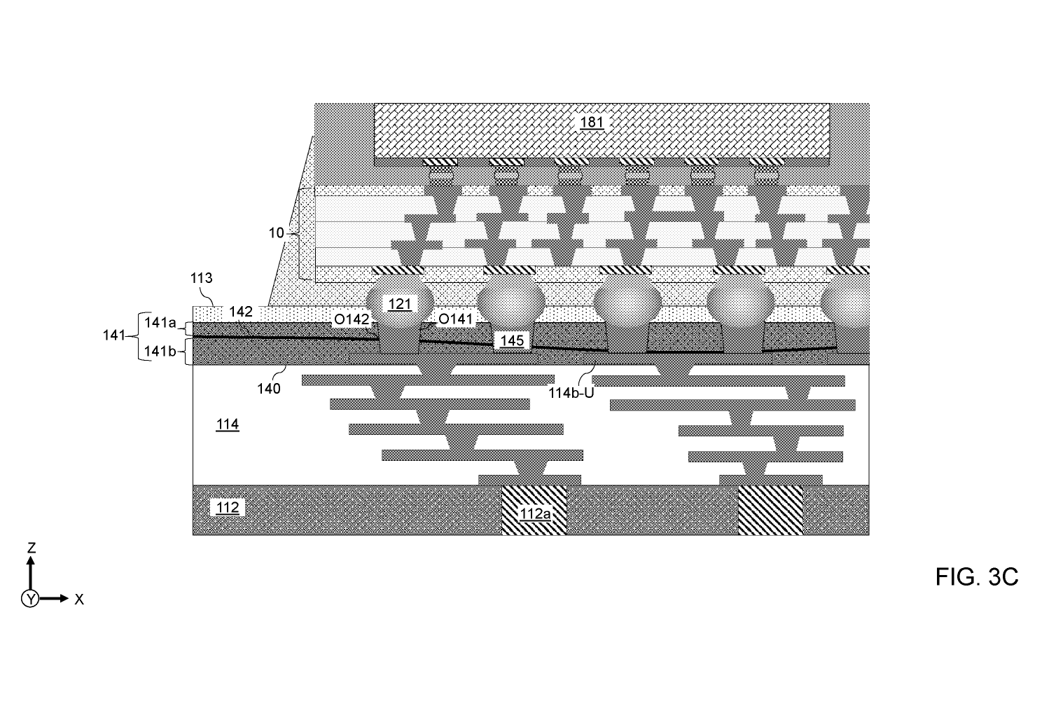

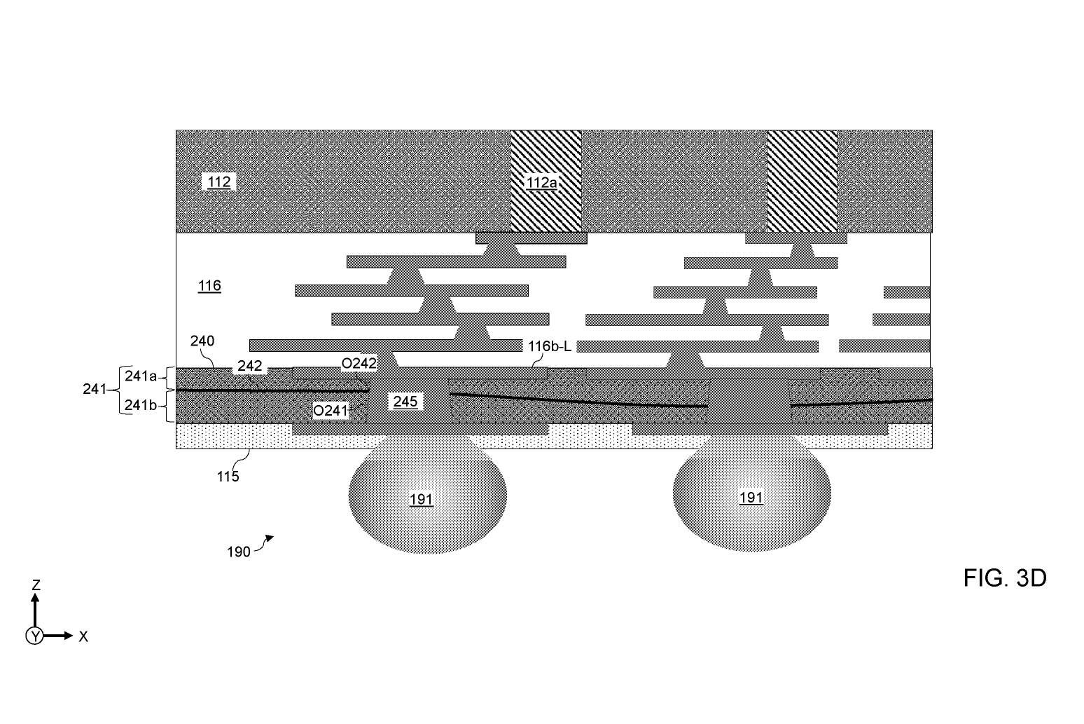

FIGS. 3A-3D are various views of a package structure 100 including the package substrate 110 according to one or more embodiments. FIG. 3A is a vertical cross-sectional view of the package structure 100 according to one or more embodiments. FIG. 3B is a plan view (top-down view) of the package structure 100, according to one or more embodiments. The view in FIG. 3A is along the line A-A’ in FIG. 3B. FIG. 3C is a vertical cross-sectional view of the upper fiber-reinforced dielectric layer 140 according to one or more embodiments. FIG. 3D is a vertical cross-sectional view of the lower fiber-reinforced dielectric layer 240 according to one or more embodiments.

As illustrated in FIG. 3A, the package structure 100 may include the package substrate 110. The package structure 100 may also include a semiconductor module 120 (e.g., chip on wafer (CoW) on the package substrate 110 and a stiffener ring 150 around the semiconductor module 120 on the package substrate 110. In at least one embodiment, the semiconductor module 120 may include a high performance computing (HPC) module including multiple dies. In at least one embodiment, the semiconductor module 120 may be replaced by a multi-chip module (McM).

The semiconductor module 120 may be mounted on the die mounting region 110a of the package substrate 110 (see FIG. 1). The stiffener ring 150 may be mounted on a ring mounting region 110b of the package substrate 110 (see FIG. 1). The semiconductor module 120 and the stiffener ring 150 may be separated by the separation region 110c of the package substrate 110 (see FIG. 1).

In at least one embodiment, the semiconductor module 120 may include one or more semiconductor dies 180 on an interposer 10. The semiconductor dies 180 may include any combination of a first semiconductor die 181, a second semiconductor die 182, and a third semiconductor die 183. The semiconductor module 120 is not limited to any particular configuration. The semiconductor module 120 may include, for example, a flip chip-chip scale package (FC-CSP) design, a chip-on-wafer-on-substrate design, an integrated fan-out design, and so on.

The interposer 10 is not necessarily limited to any particular materials or configuration. The interposer 10 may include, for example, organic material (e.g., dielectric polymer), inorganic material (e.g., silicon), glass substrate, etc. In at least one embodiment, the interposer 10 may include a plurality of dielectric material layers 12 and a plurality of redistribution layers 12a stacked alternately. The number of the dielectric material layers 12 and/or the number of redistribution layers 12a in the interposer 10 are not limited by the disclosure.

In at least one embodiment, the dielectric material layers 12 may include, for example, polyimide (PI), epoxy resin, acrylic resin, phenol resin, benzocyclobutene (BCB), polybenzoxazole (PBO), or any other suitable polymer-based dielectric material. The redistribution layers 12a may include conductive materials such as metals or metal alloys. In at least one embodiment, the redistribution layers 12a may include copper, aluminum, nickel, titanium, a combination thereof or other suitable metals or metal alloys.

The redistribution layers 12a may include metallic connection structures, i.e., metallic structures that provide electrical connection between nodes in the structure. The redistribution layers 12a may include a metallic seed layer and a metallic fill material on the metallic seed layer. The metallic seed layer may include, for example, a stack of a titanium barrier layer and a copper seed layer. The titanium barrier layer may have thickness in a range from 50 nm to 500 nm, and the copper seed layer may have a thickness in a range from 50 nm to 500 nm. The metallic fill material for the redistribution layers 12a may include copper, nickel, or copper and nickel. Other suitable metallic fill materials are within the contemplated scope of disclosure. The thickness of the metallic fill material that is deposited for each redistribution layer 12a may be in a range from 2 microns to 40 microns, such as from 4 microns to 10 microns, although lesser or greater thicknesses may also be used.

In at least one embodiment, the redistribution layers 12a may include a plurality of traces (lines) and a plurality of vias connecting the plurality traces to each other. The traces may be respectively located on the dielectric material layers 12 and may extend in the x-direction (first horizontal direction) and y-direction (second horizontal direction) on an upper surface of the dielectric material layers 12.

The interposer 10 may also include an upper passivation layer 13 on the chip-side surface of the interposer 10. The upper passivation layer 13 may include, for example, silicon dioxide (SiO₂), silicon nitride (Si₃N₄), polyimide, benzocyclobutene (BCB), silicon carbide (SiC), phosphosilicate glass (PSG), aluminum oxide (Al₂O₃), titanium nitride (TiN), a combination thereof or other suitable material.

The interposer 10 may also include a lower passivation layer 14 on the board-side surface of the interposer 10. The lower passivation layer 14 may be formed of the same materials as the upper passivation layer 13. The lower passivation layer 14 may include, for example, silicon dioxide (SiO₂), silicon nitride (Si₃N₄), polyimide, benzocyclobutene (BCB), silicon carbide (SiC), phosphosilicate glass (PSG), aluminum oxide (Al₂O₃), titanium nitride (TiN), a combination thereof or other suitable material.

The interposer 10 may also include interposer lower bonding pads 14a on the lowermost dielectric material layer 12. The interposer lower bonding pads 14a may be bonded to and electrically connected to the redistribution layers 12a. The interposer lower bonding pads 14a may be formed in the lower passivation layer 14. The lower passivation layer 14 may at least partially cover the interposer lower bonding pads 14a. That is, the interposer lower bonding pads 14a may be at least partially exposed on the board-side surface of the interposer 10. The interposer lower bonding pads 14a may also include, for example, one or more layers and may include metals, metal alloys, and/or other metal-containing compounds (e.g., Cu, Al, Mo, Co, Ru, W, Ti, TiN, Ta, TaN, WN, etc.). Other suitable metal materials are within the contemplated scope of disclosure.

The semiconductor module 120 may also include a plurality of C4 bumps 121 on the board-side surface of the interposer 10. The C4 bumps 121 may be formed on the interposer lower bonding pads 14a on the board-side surface of the interposer 10, respectively. The C4 bumps 121 may be bonded to and electrically coupled to the upper metal vias 145 in the upper fiber-reinforced dielectric layer 140 of the package substrate 110. The C4 bumps 121 may include underbump metallurgy (UBM) layers (not shown) on the interposer lower bonding pads 14a. The C4 bumps 121 may further include a contact pad (e.g., copper/nickel contact pad) (not shown) on the UBM layers and a solder bump (e.g., SnAg solder bump) on the contact pad.

The semiconductor dies 180 may be attached to the chip-side of the interposer 10. The semiconductor dies 180 may include one or more first semiconductor dies 181, one or more second semiconductor dies 182 and one or more third semiconductor dies 183. In at least one embodiment, the first semiconductor dies 181 may include system on chip (SoC) dies, the second semiconductor dies 182 may include high bandwidth memory (HBM) dies and the third semiconductor dies 183 may include input/output (I/O) dies. Although the semiconductor module 120 is illustrated as including a particular number of the semiconductor dies 180 of particular sizes having a particular arrangement, the number of semiconductor dies 180, the sizes of the semiconductor dies 180 and the arrangement of the semiconductor dies 180 is not limited to any particular number, size and arrangement. In particular, the semiconductor module 120 may include any number, size and arrangement of the semiconductor dies 180.

Generally, a thickness in the z-direction of each of the semiconductor dies 180 may be substantially the same. Thus, the upper surfaces of each of the first semiconductor die 181, second semiconductor die 182 and third semiconductor die 183. may be substantially coplanar (e.g., formed in the same x-y plane), and referred to collectively as the semiconductor die upper surface 180a.

Each of the semiconductor dies 180 may include, for example, a singular semiconductor die structure, a system on chip die, or a system on integrated chips die, and may be implemented by chip-on-wafer-on-substrate technology or integrated fan-out on substrate technology. In particular, each of the semiconductor dies 180 may include, for example, a semiconductor chip or chiplet for a high performance computing (HPC) application, an artificial intelligence (AI) application, and a 5G cellular network application, a logic die (e.g., mobile application processor, microcontroller, etc.), or a memory die (e.g., HBM die, hybrid memory cube (HMC), dynamic random access memory (DRAM) die, a Wide I/O die, a M-RAM die, a R-RAM die, a NAND die, static random access memory (SRAM), etc. ), a central processing unit (CPU) chip, graphics processing unit (GPU) chip, field-programmable gate array (FPGA) chip, networking chip, application-specific integrated circuit (ASIC) chip, artificial intelligence/deep neural network (AI/DNN) accelerator chip, etc., a co-processor, accelerator, an on-chip memory buffer, a high data rate transceiver die, a I/O interface die, an IPD die, a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), a monolithic 3D heterogeneous chiplet stacking die, etc. Other dies are within the contemplated scope of this disclosure. In at least one embodiment, the first semiconductor die 181 may include a primary die (e.g., SOC die), and the second semiconductor dies 182 and third semiconductor dies 183 may include an ancillary die (e.g., memory/SOC die, HBM die, etc.).

The semiconductor dies 180 may also include a die passivation layer 185 on a bottom surface of the semiconductor dies 180. The die passivation layer 185 may include, for example, silicon dioxide (SiO₂), silicon nitride (Si₃N₄), polyimide, benzocyclobutene (BCB), silicon carbide (SiC), phosphosilicate glass (PSG), aluminum oxide (Al₂O₃), titanium nitride (TiN), a combination thereof or other suitable material.

The semiconductor dies 180 may also include die bonding pads 185ain the die passivation layer 185. The die bonding pads 185a may be electrically connected to the redistribution layers 12a of the interposer 10 by microbumps 128. The die bonding pads 185a may include, for example, one or more layers and may include metals, metal alloys, and/or other metal-containing compounds (e.g., Cu, Al, Mo, Co, Ru, W, Ti, TiN, Ta, TaN, WN, etc.). Other suitable metal materials are within the contemplated scope of disclosure.

The semiconductor module 120 may also include an upper molding layer 127 formed around the semiconductor dies 180. The upper molding layer 127 may have an outer sidewall that is substantially aligned with the outer sidewall of the interposer 10. The upper molding layer 127 may also have an upper surface that is substantially uniform (e.g., flat) and substantially coplanar with the upper surface 180a of the semiconductor dies 180.

The upper molding layer 127 may be formed on outer sidewalls of each of the semiconductor dies 180. The upper molding layer 127 may be bonded to the outer sidewalls of each of the semiconductor dies 180. The upper molding layer 127 may also be formed in a die-to-die gap between the semiconductor dies 180 and bonded to the inner sidewalls of the semiconductor dies 180. The upper molding layer 127 may also be bonded to the chip-side surface of the interposer 10 (e.g., the upper passivation layer 13).

In at least one embodiment, the upper molding layer 127 may be formed of a curable material that may cure to form a hard, solid structure. The upper molding layer 127 may include, for example, epoxy molding compound (EMC). In at least one embodiment, the upper molding layer 127 may include a polymeric material and in particular, an epoxy-based polymeric material. Other suitable molding materials may be used.

In at least one embodiment, the upper molding layer 127 may have a coefficient of thermal expansion (CTE) that is substantially similar to a CTE of the interposer 10. In at least one embodiment, the upper molding layer 127 may include an added material (e.g., filler material added to a polymeric material) for improving a property of the upper molding layer 127 (e.g., thermal conductivity, CTE, etc.). The added material may include, for example, metal powder, metal oxide powder, etc. Other materials in the upper molding layer 127 are within the contemplated scope of the disclosure.

The stiffener ring 150 may be mounted on the package substrate 110 around the semiconductor module 120. The stiffener ring 150 may be securely fixed to the package substrate 110 by an adhesive 160 (e.g., a silicone adhesive or an epoxy adhesive). The stiffener ring 150 may be formed of a metal such as copper with a nickel coating, or an aluminum alloy. The stiffener ring 150 may provide rigidity to the package substrate 110. In at least one embodiment, the stiffener ring 150 may be replaced with the package lid that is over the semiconductor module 120 and attached to the package substrate 110 by the adhesive 160.

A ball-grid array (BGA) 190 including a plurality of solder balls 191 may be formed on the board-side surface of the package substrate 110. The solder balls 191 may allow the semiconductor package 100 to be securely mounted on a substrate such as a printed circuit board (PCB) and electrically coupled to the PCB substrate. The solder balls 191 may contact the bonding pads 246 on the lower fiber-reinforced dielectric layer 240, respectively.

Referring again to FIG. 3B, the package underfill layer 129 has been omitted from FIG. 3B for ease of understanding. As illustrated in FIG. 3B, the semiconductor module 120 may be located in a central region of the package substrate 110. A center (in the x direction and y-direction) of the semiconductor module 120 may be substantially aligned with a center of the package substrate 110. The semiconductor module 120 may have a substantially rectangular outer shape. Other shapes are within the contemplated scope of disclosure.

The separation region 110c of the package substrate 110 may be located around an entire periphery of the semiconductor module 120. The separation region 110c may have a width W110c that is substantially uniform around the entire periphery of the semiconductor module 120. The separation region 110c may have a substantially frame shape.

The stiffener ring 150 may be formed around an entire periphery of the semiconductor module 120. The solder balls 191 of the BGA 190 may be located under the stiffener ring 150 and under the semiconductor module 120. The stiffener ring 150 may have a frame shape. The stiffener ring 150 may have a substantially rectangular outer shape. Other shapes are within the contemplated scope of disclosure. A center (in the x direction and y-direction) of the stiffener ring 150 may be substantially aligned with a center of the package substrate 110 and/or a center of the semiconductor module 120.

The package substrate 110 may include an outer package substrate region 110e between the stiffener ring 150 and an outer edge of the package substrate 110. The outer package substrate region 110e may have a width W110e. The width W110e may be substantially uniform around an entire periphery of the stiffener ring 150. In at least one embodiment, the width W110e of the outer package substrate region 110e may be less than the width W110c of the separation region 110c.

As further illustrated in FIG. 3B, the package substrate 110 may have a substantially rectangular shape. Other shapes are within the contemplated scope of disclosure. The outer edge of the upper fiber-reinforced dielectric layer 140 and the outer edge of the lower fiber-reinforced dielectric layer 240 may be substantially coextensive with the outer edge of the package substrate 110. In particular, the upper fiber-reinforced dielectric layer 140 and the lower fiber-reinforced dielectric layer 240 may both be formed over an entire area of the package substrate 110.

As illustrated in FIG. 3C, the dielectric material 141 in the upper fiber-reinforced dielectric layer 140 may include a dielectric material top portion 141a on top of the fiber sheet 142. The dielectric material top portion 141a may have a thickness that is at least 5% of the total thickness of the upper fiber-reinforced dielectric layer 140. The dielectric material 141 may have a dielectric material bottom portion 141b on bottom of the fiber sheet 142. The dielectric material bottom portion 141b may also have a thickness that is at least 5% of the total thickness of the upper fiber-reinforced dielectric layer 140. The dielectric material 141 may also include connecting portions (not shown) that connect the dielectric material top portion 141a to the dielectric material bottom portion 141b through the openings O42 between the fibers 42 in the fiber sheet 142 (see FIGS. 2A-2B).

As further illustrated in FIG. 3C, the upper metal vias 145 in the upper fiber-reinforced dielectric layer 140 may extend in the z-direction through openings O141 in the dielectric material 141 and openings O142 in the fiber sheet 142. The openings O142 may have a diameter that is in a range from 105% to 125% of the greatest diameter of the upper metal vias 145.

As illustrated in FIG. 3D, the dielectric material 241 in the lower fiber-reinforced dielectric layer 240 may include a dielectric material top portion 241a on top of the fiber sheet 142. The dielectric material top portion 241amay have a thickness that is at least 5% of the total thickness of the lower fiber-reinforced dielectric layer 240. The dielectric material 241 may have a dielectric material bottom portion 241bon bottom of the fiber sheet 142. The dielectric material bottom portion 241b may also have a thickness that is at least 5% of the total thickness of the lower fiber-reinforced dielectric layer 240. The dielectric material 241 may also include connecting portions (not shown) that connect the dielectric material top portion 241a to the dielectric material bottom portion 241b through the openings O42 between the fibers 42 in the fiber sheet 142 (see FIGS. 2A-2B).

As further illustrated in FIG. 3D, the lower metal vias 245 in the lower fiber-reinforced dielectric layer 240 may extend in the z-direction through openings O241 in the dielectric material 241 and openings O242 in the fiber sheet 142. The openings O242 may have a diameter that is in a range from 105% to 125% of the greatest diameter of the lower metal vias 245.

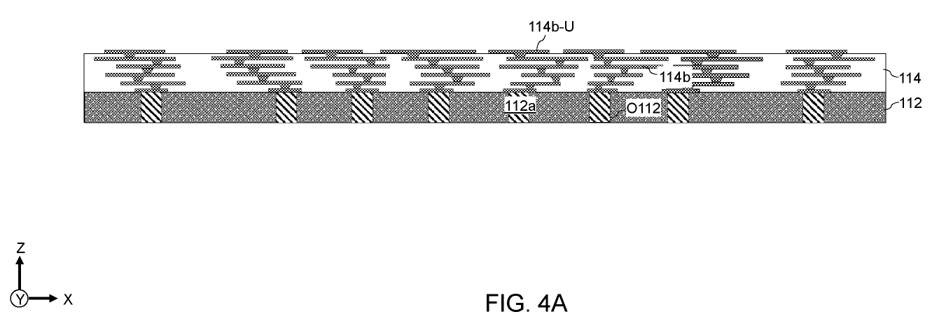

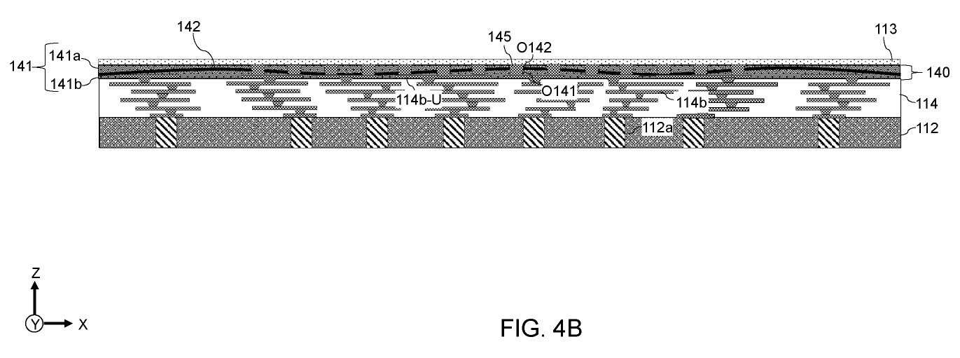

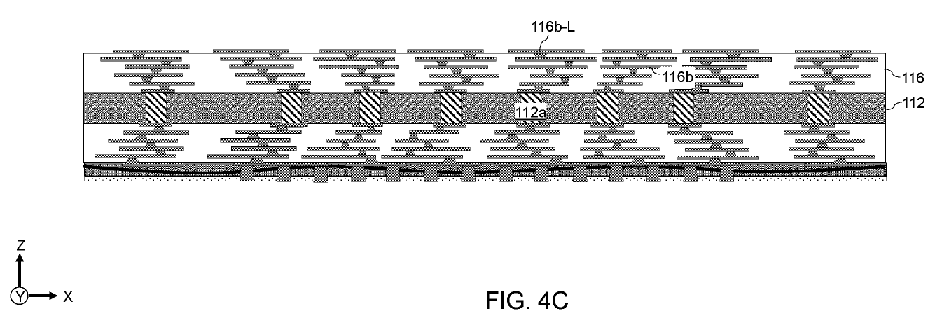

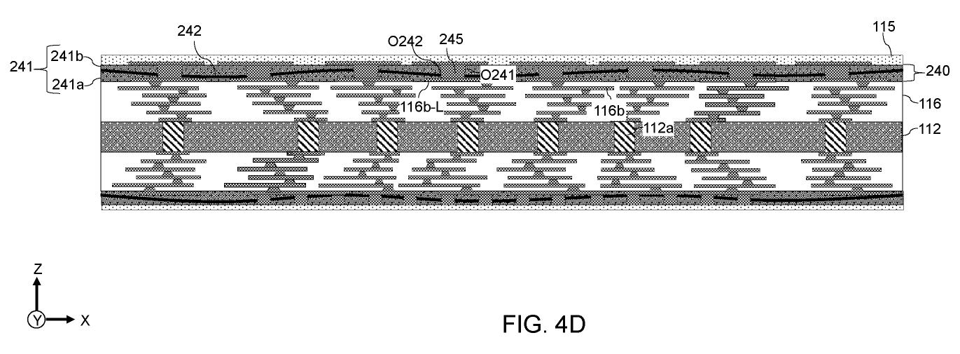

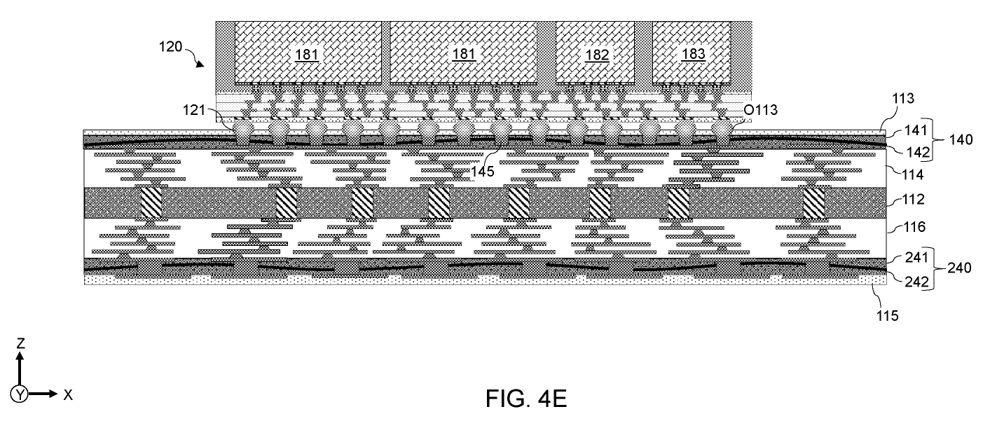

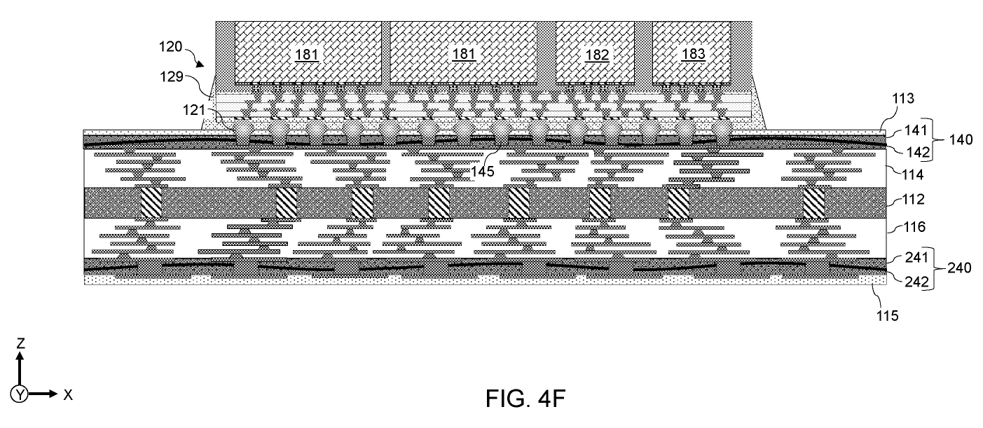

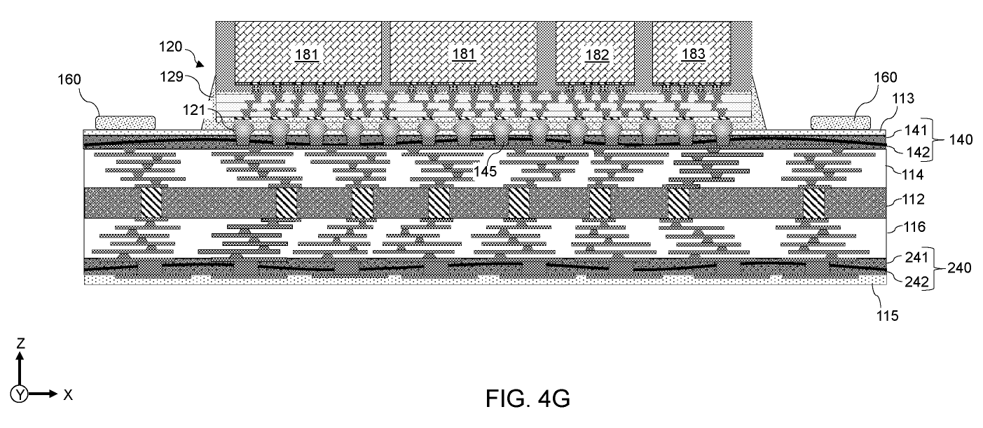

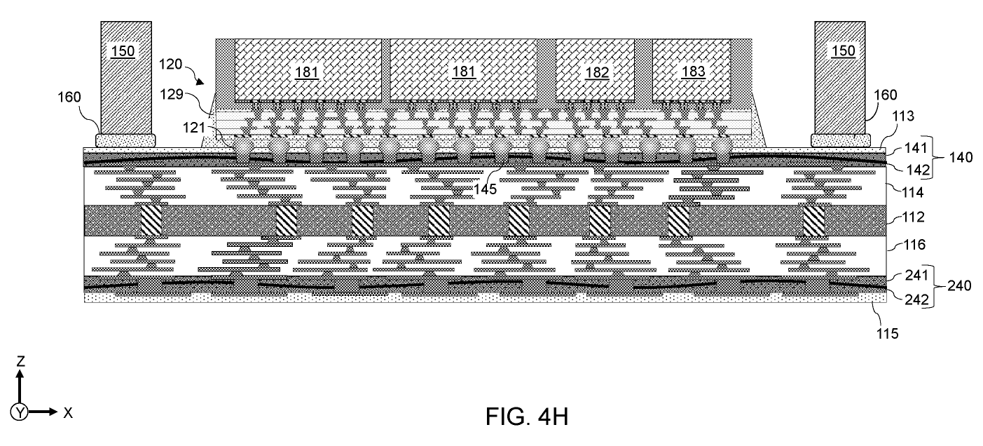

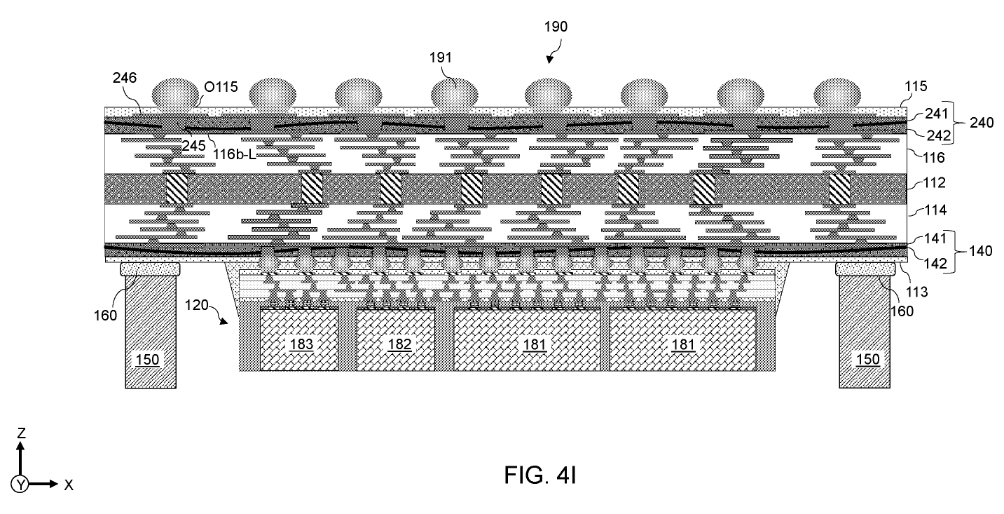

FIGS. 4A-4I are vertical cross-sectional views of intermediate structures in a method of making the package structure 100 according to one or more embodiments.

FIG. 4A is a vertical cross-sectional view of an intermediate structure including the first dielectric layer 114 on the core 112 according to one or more embodiments. The core 112 may be formed by forming openings O112 in a core material layer (e.g., epoxy resin, woven glass laminate, etc.). The openings O112 may be formed, for example, by a laser etching process. The openings O112 may alternatively be formed by using a photolithographic process. The photolithographic process may include forming a patterned photoresist mask (not shown) on the core material layer and etching (e.g., wet etching, dry etching, etc.) the exposed upper surface of the core material layer through openings in the photoresist mask. The photoresist mask may be subsequently removed by ashing, dissolving the photoresist mask or by consuming the photoresist mask during the etch process.

The through vias 112a may then be formed in the openings O112 (e.g., through holes in the core 112). The through vias 112a may be formed, for example, by depositing a metal layer (e.g., copper, aluminum or other suitable conductive materials) in the openings O112 and on an upper surface of the core material layer by CVD, PVD or other suitable deposition technique. The metal layer may be deposited, for example, by CVD, PVD or other suitable process. The metal layer may be etched (e.g., by wet etching, dry etching, etc.) so as to form the through vias 112a and complete the formation of the core 112.

The first dielectric layer 114 may then be formed on the core 112. The first dielectric layer 114 may include a plurality of dielectric layers that may be formed, for example, by chemical vapor deposition (CVD), physical vapor deposition (PVD), spin coating, lamination or other suitable deposition technique.

The metal layers (e.g., traces) and metal vias of the first metal interconnect structures 114b may be formed layer-by-layer at the time of forming the plurality of dielectric layers of the first dielectric layer 114. The first metal interconnect structures 114b may be formed so as to contact the through vias 112a in the core 112. Formation of the first dielectric layer 114 may be completed by the forming of the uppermost metal trace 114b-U on the upper surface of the first dielectric layer 114.

The metal layers (e.g., traces) and metal vias of the first metal interconnect structures 114b may be formed by a semi-additive process (SAP). The semi-additive process may include depositing (e.g., by CVD, PVD or other suitable process) a seed layer (e.g., copper seed layer) on a dielectric layer (e.g., using electroless copper plating), depositing (e.g., by CVD, PVD or other suitable process) a photoresist layer on the seed layer, exposing and developing the photoresist layer to form a patterned photoresist layer, electroplating exposed areas of the seed layer through openings in the patterned photoresist layer, stripping away the photoresist layer, and etching away the portion of the seed layer that was not electroplated.

FIG. 4B is a vertical cross-sectional view of an intermediate structure including the upper fiber-reinforced dielectric layer 140 according to one or more embodiments. The upper fiber-reinforced dielectric layer 140 may be formed on the first dielectric layer 114 by a series of steps. First, the dielectric material bottom portion 141b may be deposited (e.g., by CVD, PVD or other suitable process) on the first dielectric layer 114. Then, the fiber sheet 142 may be placed on the dielectric material bottom portion 141b. In at least one embodiment, the fiber sheet 142 may be placed on the dielectric material bottom portion 141b by an electromechanical pick-and-place (PNP) machine. The dielectric material top portion 141a may then be deposited (e.g., by CVD, PVD or other suitable process) on fiber sheet 142. The dielectric material top portion 141a may be deposited on a surface of the dielectric material bottom portion 141b through the openings O142 between the fibers 42 in the fiber sheet 142 (see FIGS. 2A-2B).

The openings O142 in the fiber sheet 142 and the openings O141 in the dielectric material 141 may be formed in the same step. The openings O141 and openings O142 may be formed, for example, by a laser etching process. The openings O141 and openings O142 may alternatively or additionally be formed by using a photolithographic process. The photolithographic process may include forming a patterned photoresist mask (not shown) on the dielectric material 141 and etching (e.g., wet etching, dry etching, etc.) the exposed upper surface of the dielectric material 141 through openings in the photoresist mask. The photoresist mask may be subsequently removed by ashing, dissolving the photoresist mask or by consuming the photoresist mask during the etch process.

The upper metal vias 145 may then be formed in an openings O141 and openings O142. The upper metal vias 145 may be formed so as to contact the uppermost metal trace 114b-U of the first metal interconnect structures 114b. The upper metal vias 145 may be formed by depositing (e.g., by CVD, PVD or other suitable process) a metal layer (e.g., copper, aluminum or other suitable conductive materials) on the dielectric material 141 and in the openings O141 and openings O142. The metal layer may then be removed from the upper surface of the dielectric material 141 by etching (e.g., by wet etching, dry etching, etc.) so as to form the upper metal vias 145. The solder resist layer 113 may then be formed on the upper fiber-reinforced dielectric layer 140 by CVD, PVD or other suitable deposition process.

FIG. 4C is a vertical cross-sectional view of an intermediate structure including the second dielectric layer 116 on the core 112 according to one or more embodiments. As illustrated in FIG. 4C, the intermediate structure in FIG. 4B may be inverted, and the second dielectric layer 116 formed on the core 112.

The process of forming the second dielectric layer 116 may be substantially similar to the method of forming the first dielectric layer 114. The second dielectric layer 116 may include a plurality of dielectric layers that may be formed, for example, by chemical vapor deposition (CVD), physical vapor deposition (PVD), spin coating, lamination or other suitable deposition technique. The metal layers (e.g., traces) and metal vias of the second metal interconnect structures 116b may be formed layer-by-layer at the time of forming the plurality of dielectric layers of the second dielectric layer 116. The second metal interconnect structures 116b may be formed so as to contact the through vias 112a in the core 112. Formation of the second dielectric layer 116 may be completed by the forming of the lowermost metal trace 116b-L on the lower surface of the second dielectric layer 116. The metal layers (e.g., traces) and metal vias of the second metal interconnect structures 116b may also be formed by a semi-additive process (SAP) described above with respect to the first metal interconnect structures 114b.

FIG. 4D is a vertical cross-sectional view of an intermediate structure including the lower fiber-reinforced dielectric layer 240 according to one or more embodiments. The lower fiber-reinforced dielectric layer 240 may be formed on the second dielectric layer 116 by a series of steps. First, the dielectric material top portion 241a may be deposited (e.g., by CVD, PVD or other suitable process) on the second dielectric layer 116. Then, the fiber sheet 142 may be placed on the dielectric material top portion 141a. In at least one embodiment, the fiber sheet 142 may be placed on the dielectric material top portion 241b by an electromechanical pick-and-place (PNP) machine. The dielectric material bottom portion 241b may then be deposited (e.g., by CVD, PVD or other suitable process) on the fiber sheet 142. The dielectric material bottom portion 241b may be deposited on a surface of the dielectric material top portion 241a through the openings O42 between the fibers 42 in the fiber sheet 142 (see FIGS. 2A-2B).

The openings O242 in the fiber sheet 142 and the openings O241 in the dielectric material 241 may be formed in the same step. The openings O241 and openings O242 may be formed, for example, by a laser etching process. The openings O241 and openings O242 may alternatively or additionally be formed by using a photolithographic process. The photolithographic process may include forming a patterned photoresist mask (not shown) on the dielectric material 241 and etching (e.g., wet etching, dry etching, etc.) the exposed upper surface of the dielectric material 241 through openings in the photoresist mask. The photoresist mask may be subsequently removed by ashing, dissolving the photoresist mask or by consuming the photoresist mask during the etch process.

The lower metal vias 245 may then be formed in an openings O241 and openings O242. The lower metal vias 245 may be formed so as to contact the lowermost metal trace 116b-L of the second metal interconnect structures 116b. The lower metal vias 245 may be formed by depositing (e.g., by CVD, PVD or other suitable process) a metal layer (e.g., copper, aluminum or other suitable conductive materials) on the dielectric material 241 and in the openings O241 and openings O242. The metal layer may then be removed from the upper surface of the dielectric material 241 by etching (e.g., by wet etching, dry etching, etc.) so as to form the lower metal vias 245. The solder resist layer 115 may then be formed on the lower fiber-reinforced dielectric layer 240 by CVD, PVD or other suitable deposition process.

FIG. 4E illustrates a vertical cross-sectional view of an intermediate structure in which the semiconductor module 120 may be mounted on the package substrate 110 (e.g., via a flip chip bonding (FCB) process) according to one or more embodiments.

Solder resist openings (SROs) O113 may be formed over the upper metal vias 145, respectively to expose an upper surface of the upper metal vias 145 through the SROs O113. The SROs O113 may be formed by a photolithographic process. The photolithographic process may include forming a patterned photoresist mask (not shown) on the upper solder resist layer 113 and etching (e.g., wet etching, dry etching, etc.) the exposed upper surface of the upper solder resist layer 113 through openings in the photoresist mask. The photoresist mask may be subsequently removed by ashing, dissolving the photoresist mask or by consuming the photoresist mask during the etch process. The SROs O113 may have a tapered sidewall so that a diameter of the SRO 113 (in the X-Y plane) may decrease in a direction toward the upper metal vias 145.

The semiconductor module 120 may be positioned over the package substrate 110 (e.g., by an electromechanical PNP machine) so that the C4 bumps 121 of the semiconductor module 120 are over the upper metal vias 145 on the package substrate 110. The semiconductor module 120 may then be lowered so that the C4 bumps 121 contact the upper surface of the upper metal vias 145. The intermediate structure may then be heated in order to bond the solder portion of the C4 bumps 121 to a part of the upper metal vias 145 that is exposed through the upper solder resist layer 113.

FIG. 4F illustrates a vertical cross-sectional view of an intermediate structure in which the package underfill layer 129 may be formed on the package substrate 110 according to one or more embodiments. The package underfill layer 129 may be formed of an epoxy-based polymeric material. As illustrated in FIG. 4F, the package underfill layer 129 may be formed under and around the semiconductor module 120 and the C4 bumps 121 so as to fix the semiconductor module 120 to the package substrate 110. The package underfill layer 129 may then be cured, for example, in a box oven for about 90 minutes at about 150°C to provide the package underfill layer 129 with a sufficient stiffness and mechanical strength.

FIG. 4G illustrates a vertical cross-sectional view of an intermediate structure in which the adhesive 160 may be applied to the package substrate 110 according to one or more embodiments. The adhesive 160 may include, for example, a silicone adhesive or an epoxy adhesive. The adhesive 160 may be applied, for example, on ring mounting region 100b of the package substrate 110 (see FIG. 1A). The adhesive 160 may be applied to have a width and shape corresponding to a width and shape of the stiffener ring 150. The adhesive 160 may be formed as a continuous bead around an entire periphery of the semiconductor module 120. The adhesive 160 may be dispensed on a surface of the package substrate 110 in a quantity sufficient to securely bond the stiffener ring 150 to the package substrate 110.

FIG. 4H illustrates a vertical cross-sectional view of an intermediate structure in which the stiffener ring 150 may be attached to (e.g., mounted on) the package substrate 110 according to one or more embodiments. The stiffener ring 150 may be composed of metal material (e.g., aluminum) and may be formed, for example, by milling using a computer numerical control (CNC) milling machine.

The package substrate 110 with the semiconductor module 120 may be placed on a surface and the stiffener ring 150 lowered down onto the package substrate 110 around the semiconductor module 120. The stiffener ring 150 may then be aligned with the adhesive 160 formed on the package substrate 110. The stiffener ring 150 may then be pressed downward by applying a pressing force down onto the stiffener ring 150 so that the stiffener ring 150 may be fixed to the package substrate 110 through the adhesive 160.

Alternatively, the stiffener ring 150 may be placed on a surface (e.g., a flat surface), and the package substrate 110 inverted and lowered onto the stiffener ring 150. That is, the semiconductor module 120 is inserted into the stiffener ring 150. The package substrate 110 and semiconductor module 120 may then be pressed by applying a pressing force down into stiffener ring 150 so that the stiffener ring 150 is fixed to the package substrate 110 through the adhesive 160.

The stiffener ring 150 may be clamped to the package substrate 110 for a period to allow the adhesive 160 to cure and form a secure bond between the package substrate 110 and the stiffener ring 150. The clamping of the stiffener ring 150 to the package substrate 110 may be performed, for example, by using a heat clamp module. The heat clamp module may apply a uniform force across the upper surface of the stiffener ring 150.

FIG. 4I illustrates a vertical cross-sectional view of an intermediate structure in which a plurality of solder balls 191 may be formed on the package substrate 110 according to one or more embodiments.

Solder resist openings (SROs) O115 may be formed over the bonding pads 246, respectively to expose a surface of the bonding pads 246 through the SROs O115. The SROs O115 may be formed by a photolithographic process. The photolithographic process may include forming a patterned photoresist mask (not shown) on the lower solder resist layer 115 and etching (e.g., wet etching, dry etching, etc.) the exposed upper surface of the lower solder resist layer 115 through openings in the photoresist mask. The photoresist mask may be subsequently removed by ashing, dissolving the photoresist mask or by consuming the photoresist mask during the etch process. The SROs O115 may have a tapered sidewall so that a diameter of the SRO O115 (in the X-Y plane) may decrease in a direction toward the bonding pad 246.

The plurality of solder balls 191 may be formed on the bonding pads 246, for example, by an electroplating process. The plurality of solder balls 191 may contact the bonding pads 246 through openings in the SROs O115. The plurality of solder balls 191 may constitute a ball-grid array (BGA) 190 that may allow the semiconductor package 100 to be securely mounted (e.g., by surface mount technology (SMT)) on a substrate such as a printed circuit board and electrically coupled to the substrate. The solder balls 191 may be formed, for example, so as to be located under the stiffener ring 150 and under the semiconductor module 120.

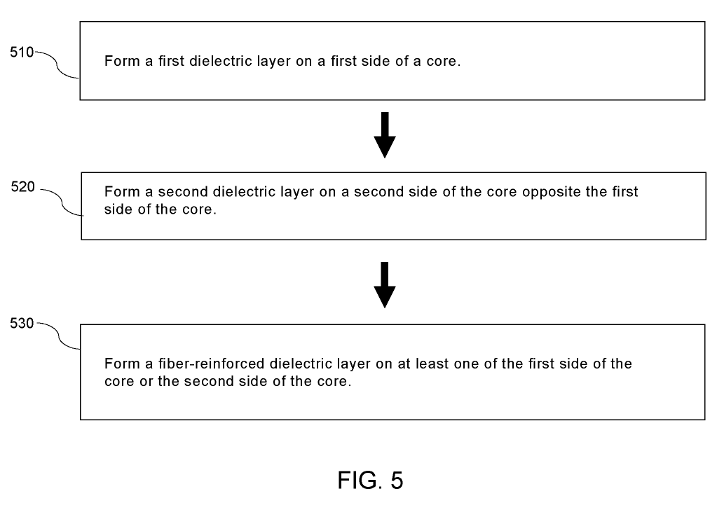

FIG. 5 is a flow chart illustrating a method of making a semiconductor package according to one or more embodiments. Step 510 includes forming a first dielectric layer on a first side of a core. Step 520 includes forming a second dielectric layer on a second side of the core opposite the first side of the core. Step 530 includes forming a fiber-reinforced dielectric layer on at least one of the first side of the core or the second side of the core.

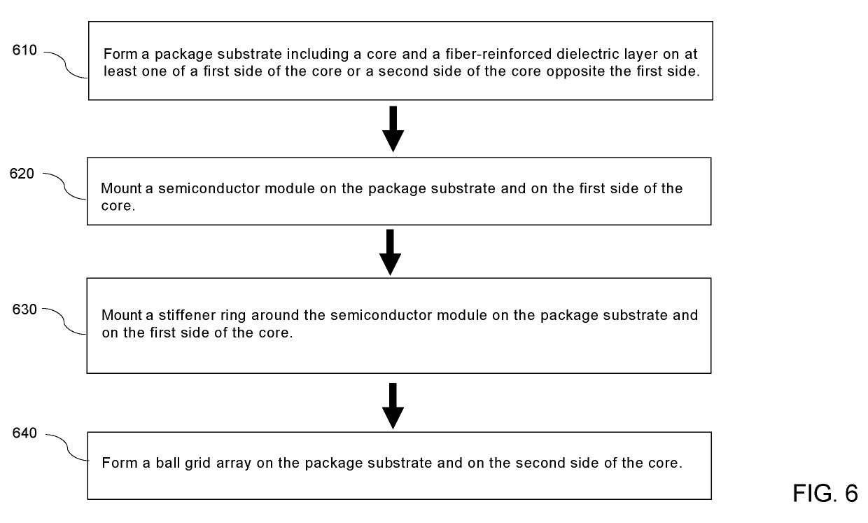

FIG. 6 is a flow chart illustrating a method of making a semiconductor package according to one or more embodiments. Step 610 includes forming a package substrate including a core and a fiber-reinforced dielectric layer on at least one of a first side of the core or a second side of the core opposite the first side. Step 620 includes mounting a semiconductor module on the package substrate and on the first side of the core. Step 630 includes mounting a stiffener ring around the semiconductor module on the package substrate and on the first side of the core. Step 640 includes forming a ball grid array on the package substrate and on the second side of the core.

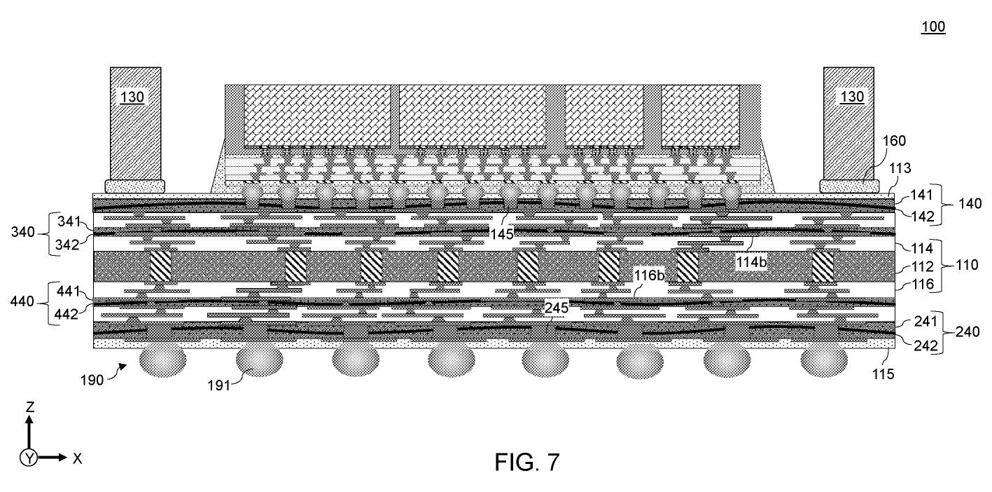

FIG. 7 is a vertical cross-sectional view of a package structure 100 having a first alternative configuration according to one or more embodiments. As illustrated in FIG. 7, the package structure having the first alternative configuration is substantially similar to the package structure in FIGS. 3A-3D. However, the package structure 100 having the first alternative configuration may include an embedded upper fiber-reinforced dielectric layer 340 embedded in the first dielectric layer 114. At least a portion of the first dielectric layer 114 may be formed on top of the embedded upper fiber-reinforced dielectric layer 340. At least a portion of the first dielectric layer 114 may be formed below the embedded upper fiber-reinforced dielectric layer 340. The embedded upper fiber-reinforced dielectric layer 340 may be substantially similar to the upper fiber-reinforced dielectric layer 140. In particular, the embedded upper fiber-reinforced dielectric layer 340 may include a dielectric material 341 (substantially the same as dielectric material 141) and a fiber sheet 342 (substantially the same as fiber sheet 142) in the dielectric material 341. However, in contrast to the upper fiber-reinforced dielectric layer 140, the embedded upper fiber-reinforced dielectric layer 340 may not include the upper metal vias 145. Further, the embedded upper fiber-reinforced dielectric layer 340 may include a portion of the first metal interconnect structures 114b. In particular, the first metal interconnect structures 114b may be formed continuously through the embedded upper fiber-reinforced dielectric layer 340.

The package structure 100 having the first alternative configuration may also include an embedded lower fiber-reinforced dielectric layer 440 embedded in the second dielectric layer 116. At least a portion of the second dielectric layer 116 may be formed on top of the embedded lower fiber-reinforced dielectric layer 440. At least a portion of the second dielectric layer 116 may be formed below the embedded lower fiber-reinforced dielectric layer 440. The embedded lower fiber-reinforced dielectric layer 440 may be substantially similar to the lower fiber-reinforced dielectric layer 240. In particular, the embedded lower fiber-reinforced dielectric layer 440 may include a dielectric material 441 (substantially the same as dielectric material 242) and a fiber sheet 442 (substantially the same as fiber sheet 142) in the dielectric material 441. However, in contrast to the lower fiber-reinforced dielectric layer 240, the embedded lower fiber-reinforced dielectric layer 440 may not include the lower metal vias 245. Further, the embedded lower fiber-reinforced dielectric layer 440 may include a portion of the second metal interconnect structures 116b. In particular, the second metal interconnect structures 116b may be formed continuously through the embedded upper fiber-reinforced dielectric layer 440.

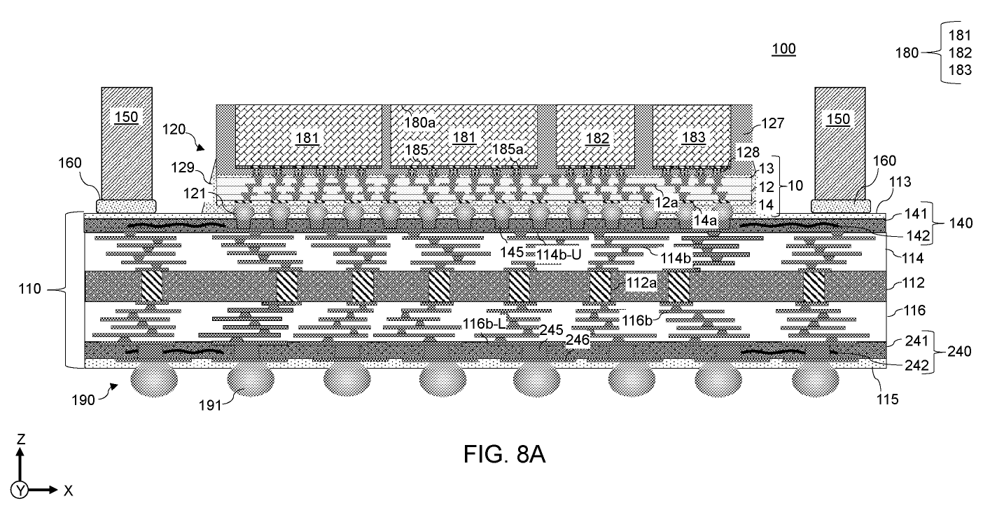

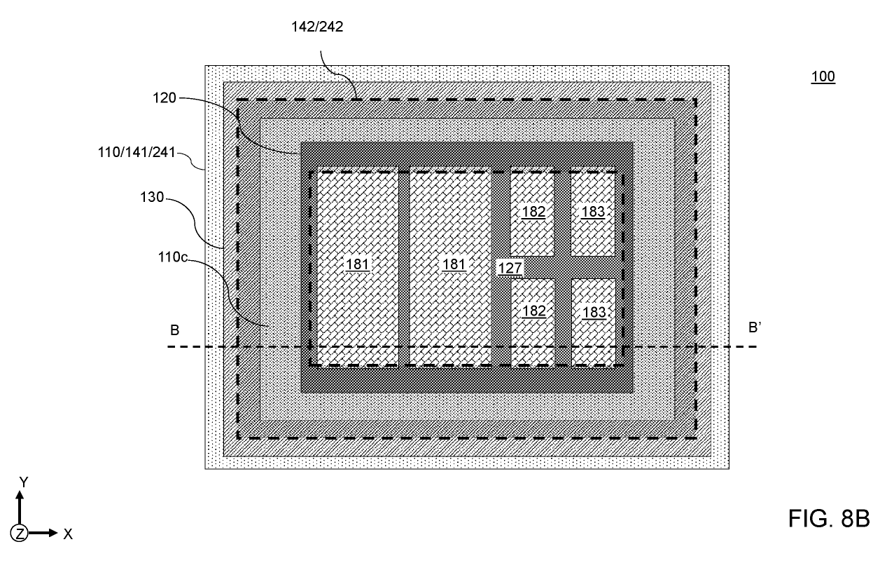

FIGS. 8A-8B are various views of the package structure 100 having a second alternative configuration according to one or more embodiments. FIG. 8A is a vertical cross-sectional view of the package structure 100 having a second alternative configuration according to one or more embodiments. FIG. 8B is a top down view (plan view) of the package structure 100 having a second alternative configuration according to one or more embodiments. The view in FIG. 8A is along the line B-B’ in FIG. 8B.

As illustrated in FIG. 8A, the package structure 100 having the second alternative configuration may be substantially the same as the package structure 100 in FIGS. 3A-3D. In particular, in the second alternative configuration, the dielectric layer 141 and the dielectric layer 241 may be located the same as in FIG. 3A-3C. However, in contrast to the package structure 100 in FIGS. 3A-3D, the package structure 100 having the second alternative configuration may include the fiber sheet 142 in only part of the upper fiber-reinforced dielectric layer 140 and include the fiber sheet 142 in only part of the lower fiber-reinforced dielectric layer 240.

Referring to FIG. 8B, a location of the fiber sheet 142 and the fiber sheet 142 are indicated by shading. An outline of the location of the fiber sheet 142 and the fiber sheet 142 is indicated by dashed lines in FIG. 8B.

As illustrated in FIG. 8B, the outer edge of the dielectric layer 141 and the outer edge of the dielectric layer 241 may be substantially aligned with an outer edge of the package substrate 110. However, the fiber sheet 142 is not necessarily located in an entirety of the dielectric layer 141 and the fiber sheet 142 is not necessarily located in an entirety of the dielectric layer 241. Instead, the fiber sheet 142 and the fiber sheet 142 may each have a frame shape located under an inner portion of the stiffener ring 150 and an outer portion of the semiconductor module 120. In particular, the fiber sheet 142 and the fiber sheet 142 may be located in the separation region 110c which may be especially susceptible to crack formation.

Referring to FIGS. 1-8B, a package substrate 110 may include a core 112, a first dielectric layer 114 on a first side of the core 112, a second dielectric layer 116 on a second side of the core 112 opposite the first side of the core 112, and a fiber-reinforced dielectric layer 20 on at least one of the first side of the core 112 or the second side of the core 112.

In one embodiment, the fiber-reinforced dielectric layer 20 may include a dielectric material 141, 241 and a fiber sheet 142, 242 embedded in the dielectric material 141, 241. In one embodiment, the fiber sheet 142, 242 may include an inorganic material including at least one of glass, SiO2, Al2O3, Ca, B, or Mg. In one embodiment, the fiber sheet 142, 242 may include one of a woven fiber sheet or a fiber mesh sheet. In one embodiment, the package substrate 110 may further include a die mounting region 110a, a ring mounting region 110b adjacent the die mounting region 110a, and a separation region 110c between the die mounting region 110a and the ring mounting region 110b, wherein the fiber-reinforced dielectric layer 20 may be located in the separation region 110c. In one embodiment, the fiber-reinforced dielectric layer 20 may include an upper fiber-reinforced dielectric layer 140 on the first side of the core 112, and a lower fiber-reinforced dielectric layer 240 on the second side of the core 112. In one embodiment, the upper fiber-reinforced dielectric layer 140 may be located on an upper surface of the first dielectric layer 114 and further includes a plurality of upper metal vias 145 extending through the fiber sheet 142. In one embodiment, the first dielectric layer 114 may include a plurality of first metal interconnect structures 114, and the plurality of upper metal vias 145 may be electrically coupled to the plurality of first metal interconnect structures 114. In one embodiment, the fiber-reinforced dielectric layer 20 may further include an embedded upper fiber-reinforced dielectric layer 340 embedded in the first dielectric layer 114. In one embodiment, the lower fiber-reinforced dielectric layer 240 may be located on a lower surface of the second dielectric layer 116 and further includes a plurality of lower metal vias 245 extending through the fiber sheet 242. In one embodiment, the second dielectric layer 116 may include a plurality of second metal interconnect structures 116, and the plurality of lower metal vias 245 may be electrically coupled to the plurality of second metal interconnect structures 116. In one embodiment, the fiber-reinforced dielectric layer 20 may further include an embedded lower fiber-reinforced dielectric layer 440 embedded in the second dielectric layer 116.

Referring again to FIGS. 1-8B, a package structure 100 may include a package substrate 110 including a core 112 including a plurality of through vias 112a, and an upper fiber-reinforced dielectric layer 140 on a first side of the core 112, including a plurality of upper metal vias 145 electrically coupled to the plurality of through vias 112a, and a semiconductor module 120 attached to the package substrate 110 on the first side of the core 112, and including a plurality of solder bumps 121 contacting the plurality of upper metal vias 145, respectively.

In one embodiment, the package structure 100 may further include a stiffener ring 150 around the semiconductor module 120 on the package substrate 110, wherein the package substrate 110 may include a separation region 110c separating the stiffener ring 150 from the semiconductor module 120 and the upper fiber-reinforced dielectric layer 140 is located in the separation region 110c. The package structure 100 may further include a lower fiber-reinforced dielectric layer 240 on a second side of the core 112, including a plurality of lower metal vias 245, and a ball grid array (BGA) 190 attached to the package substrate 110 on the second side of the core 112 and electrically coupled to the plurality of through vias 112a in the core 112 through the plurality of lower metal vias 245. The package structure 100 may further include a first dielectric layer 114 between the core 112 and the upper fiber-reinforced dielectric layer 140, and a second dielectric layer 116 between the core 112 and the lower fiber-reinforced dielectric layer 240. The package structure 100 may further include an embedded upper fiber-reinforced dielectric layer 340 embedded in the first dielectric layer 114, and an embedded lower fiber-reinforced dielectric layer 440 embedded in the second dielectric layer 116. The upper fiber-reinforced dielectric layer 140 is on an upper surface of the first dielectric layer 114 and includes a dielectric material 141 and a fiber sheet 142 in the dielectric material 141, wherein the plurality of upper metal vias 145 in the dielectric material 141 may extend through the fiber sheet 142. The lower fiber-reinforced dielectric layer 240 is on a lower surface of the second dielectric layer 116 and includes a dielectric material 241, and a fiber sheet 242 in the dielectric material 242, wherein the plurality of lower metal vias 245 in the dielectric material 241 may extend through the fiber sheet 242.

Referring again to FIGS. 1-8B, a method of forming a package substrate 110 includes forming a first dielectric layer 114 on a first side of a core 112, forming a second dielectric layer 116 on a second side of the core 112 opposite the first side of the core 112, and forming a fiber-reinforced dielectric layer 20 on at least one of the first side of the core 112 or the second side of the core 112.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package substrate comprising:
a fiber-reinforced dielectric layer including a dielectric material and a fiber sheet embedded in the dielectric material, wherein the fiber sheet comprises a plurality of fibers extending in a first direction and a plurality of fibers extending in a second direction perpendicular to the first direction, and wherein the fiber sheet includes a plurality of openings between the plurality of fibers, the plurality of openings configured to receive a plurality of metal vias extending through the fiber-reinforced dielectric layer.

2. The package substrate of claim 1, wherein the fiber sheet comprises a fiber mesh sheet, and wherein the plurality of openings have a substantially square shape.

3. The package substrate of claim 2, wherein the plurality of openings have an area in a range from 100 µm² to 5000 µm².

4. The package substrate of claim 1, wherein the fiber sheet comprises a woven fiber cloth including fibers extending in the first direction interwoven with fibers extending in the second direction.

5. The package substrate of claim 4, wherein the woven fiber cloth has a weave type including one of a plain weave or a satin weave.

6. The package substrate of claim 4, wherein the plurality of openings have an area in a range from 25 µm² to 1000 µm².

7. The package substrate of claim 1, wherein the plurality of fibers have a diameter greater than about 10 µm.

8. The package substrate of claim 1, wherein the dielectric material has a thickness greater than about 20 µm and the dielectric material has a thickness at least twice a thickness of the fiber sheet.

9. The package substrate of claim 1, wherein the fiber sheet has a thickness greater than about 10 µm.

10. A package structure comprising:
a package substrate including a die mounting region, a ring mounting region adjacent the die mounting region, and a separation region between the die mounting region and the ring mounting region; and
a fiber-reinforced dielectric layer on the package substrate, the fiber-reinforced dielectric layer including a dielectric material having a dielectric material top portion and a dielectric material bottom portion, and a fiber sheet embedded in the dielectric material between the dielectric material top portion and the dielectric material bottom portion, wherein the fiber-reinforced dielectric layer is located in the separation region.

11. The package structure of claim 10, wherein the fiber-reinforced dielectric layer further includes a plurality of metal vias extending through openings in the dielectric material and openings in the fiber sheet.

12. The package structure of claim 10, wherein the fiber-reinforced dielectric layer is configured to inhibit crack formation in the separation region of the package substrate.

13. The package structure of claim 10, further comprising a semiconductor module mounted on the die mounting region and a stiffener ring mounted on the ring mounting region, wherein the separation region separates the stiffener ring from the semiconductor module.

14. The package structure of claim 10, wherein the fiber-reinforced dielectric layer extends over an entirety of the package substrate including the die mounting region, the ring mounting region, and the separation region.

15. A method of forming a package substrate, the method comprising:
depositing a dielectric material bottom portion on a dielectric layer;
placing a fiber sheet on the dielectric material bottom portion, wherein the fiber sheet comprises a plurality of fibers composed of an inorganic material;
depositing a dielectric material top portion on the fiber sheet;
forming openings in the dielectric material top portion, the dielectric material bottom portion, and the fiber sheet; and
forming a plurality of metal vias in the openings.

16. The method of claim 15, wherein placing the fiber sheet comprises placing the fiber sheet by an electromechanical pick-and-place machine.

17. The method of claim 15, wherein the plurality of fibers are composed of at least one of glass, SiO₂ Al₂O₃ Ca, B, or Mg.

18. The method of claim 15, wherein forming the openings comprises forming the openings by a laser etching process.

19. The method of claim 15, wherein forming the plurality of metal vias comprises:
depositing a metal layer in the openings; and
removing the metal layer from an upper surface of the dielectric material top portion by etching.

20. The method of claim 15, further comprising forming a solder resist layer on the dielectric material top portion, and forming solder resist openings in the solder resist layer over the plurality of metal vias.
